(19) United States
(12) Patent Application Publication
(10) Pub. No.: US 2026/0231723 A1
(43) Pub. Date: Aug. 6, 2026

(54) ERROR DETECTION METHOD FOR SUBSTRATE PROCESSING AND RELATED APPARATUSES

(71) Applicant: Applied Materials, Inc., Santa Clara, CA (US)

(72) Inventors: Jusdon SHARPLES, Santa Clara, CA (US); Gursewak SINGH, Bangalore (IN); Shubham MATHUR, Bangalore (IN); Purnendu MISHRA, Bangalore (IN); Rajiv KUMAR, Bangalore (IN); Ying WANG, Singapore (SG); Raymond Hoiman HUNG, Palo Alto, CA (US)

(21) Appl. No.: 19/047,074

(22) Filed: Feb. 6, 2025

(51) Int. Cl. H01L 21/67; G05B 19/418

(52) U.S. Cl. CPC H10P 72/0604; G05B 19/41875; H10P 72/0606; G05B 2219/32368; G05B 2219/37558; G05B 2219/45031

(57) ABSTRACT

Embodiments of the present disclosure generally relate to methods of detecting errors during a substrate processing operation, and related apparatuses and components. In one or more embodiments, a non-transitory computer readable medium stores instructions that when executed by one or more processors of a system, cause the system to determine a presence of one or more errors of one or more components disposed within an internal volume of a processing chamber based on a video signal. The one or more errors include a displaced substrate, a dripping nozzle mechanism, a fluid present on a rotor cover, or a fluid present on a substrate.

### BACKGROUND

### Field

Embodiments of the present disclosure generally relate to methods of detecting errors during a substrate processing operation, and related apparatuses and components.

### Description of the Related Art

The cleaning of semiconductor substrates is required during the formation of integrated circuits and microelectronics, as even the smallest contaminants can significantly impact the performance and reliability of the final product. Spin-dry cleaning chambers have been developed as an effective solution. These chambers utilize centrifugal force to remove particles, liquids, and residues from the surface of semiconductor substrates, offering a fast and efficient way to ensure cleanliness without the risk of contamination from cleaning agents or static buildup. Integrated cleaning and drying (ICD) chambers are spin-dry cleaning chambers that are a part of a larger substrate processing cluster tool. During the processing of a substrate, the substrate is transferred to the ICD chamber for a cleaning process.

However, errors that occur during the cleaning process within the ICD chamber can often go undetected during substrate processing. These errors include the substrate not being properly positioned within the chamber, the substrate not drying properly, or debris being within the ICD chamber. These errors may lead to defects within the substrate that may affect device performance in later processing operations.

Therefore, there is a need in the art to determine and detect errors with the substrate and/or the ICD chamber to improve substrate processing.

### SUMMARY

Embodiments of the present disclosure generally relate to methods of detecting errors during a substrate processing operation, and related apparatuses and components.

In one or more embodiments, a processing chamber, includes an enclosure defining an internal volume. A process rotor is disposed within the internal volume having a plurality of grip pins configured to releasably hold a substrate. The process rotor is configured to rotate and to move between a lowered position and a raised position. The processing chamber further includes one or more sweep arms have a nozzle mechanism configured to apply a fluid to the substrate. A rotor cover surrounds the process rotor. An annular volume is defined between the rotor cover and the process rotor. One or more optical sensors are configured to detect of one or more components within the internal volume of the processing chamber. The one or more optical sensors are configured to transmit a video signal. A controller is in communication with the one or more optical sensors. The controller is configured to receive the video signal and identify one or more errors based on the video signal.

In one or more embodiments, a method of monitoring a process chamber includes capturing one or more images of one or more components within an internal volume of a processing chamber and generating a video signal. The method further includes determining, with a controller, a presence of one or more errors of the one or more components based on the video signal. The one or more errors include a displaced substrate, a dripping nozzle mechanism, a fluid on a rotor cover, or a fluid on a substrate.

In one or more embodiments, a non-transitory computer readable medium stores instructions that when executed by one or more processors of a system, cause the system to determine a presence of one or more errors of one or more components disposed within an internal volume of a processing chamber based on a video signal. The one or more errors include a displaced substrate, a dripping nozzle mechanism, a fluid present on a rotor cover, or a fluid present on a substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 is a schematic side cross sectional view of a processing chamber, according to one or more embodiments.

FIG. 2 is top view of a process rotor with an example arrangement of grip pins and stand-off pins, according to one or more embodiments.

FIG. 3 is a top isometric view of the processing chamber with the enclosure omitted, according to one or more embodiments.

FIG. 4 is a schematic block diagram of a method of processing a substrate, according to one or more embodiments.

FIG. 5 is a schematic block diagram of one or more sub-methods performed by the controller when analyzing one or more components within a video signal in order to determine the presence of errors within a processing chamber, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

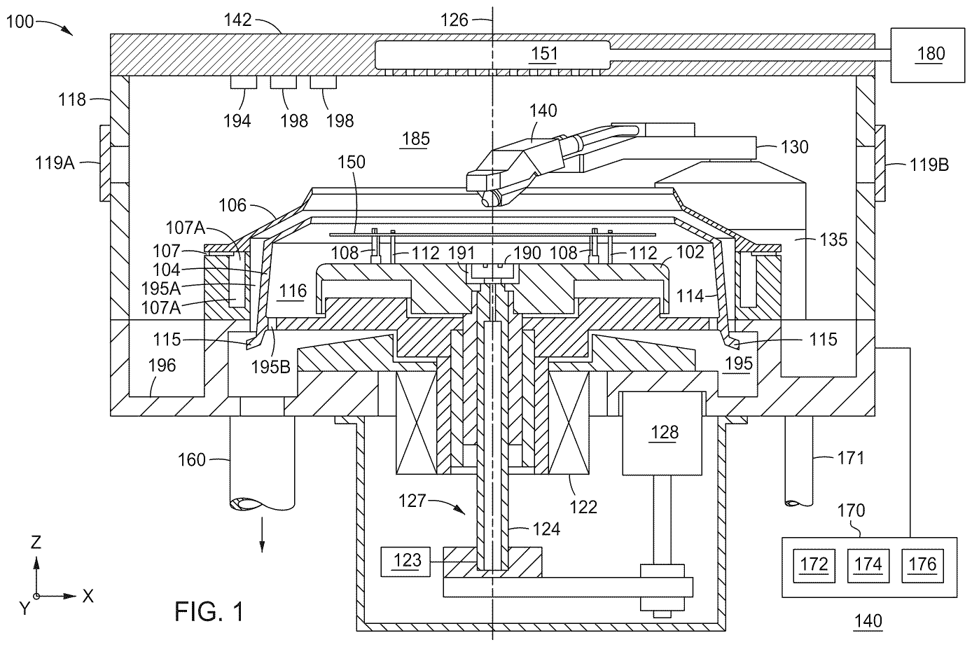

FIG. 1 is a schematic side cross sectional views of a processing chamber 100, according to one or more embodiments. In one or more embodiments, the processing chamber 100 is a spin-rinse-dry cleaning chamber. In one or more embodiments, the processing chamber 100 is an exemplary integrated cleaning and drying (ICD) chamber. During a processing operation, the processing chamber 100 receives a substrate 150 to be subject to a final clean and dry process after the substrate 150 has been cleaned within one or more of the modules of a cluster tool (not shown). The processing chamber 100 may be utilized to remove contamination from the substrate 150 that if not removed, may result in the substrate 150 not meeting contamination and defect requirements. The processing chamber 100 may also be utilized to remove residual moisture from the substrate 150 that, if not removed, may lead to subsequent re-contamination of the substrate 150 when the substrate 150 is subject to further processing.

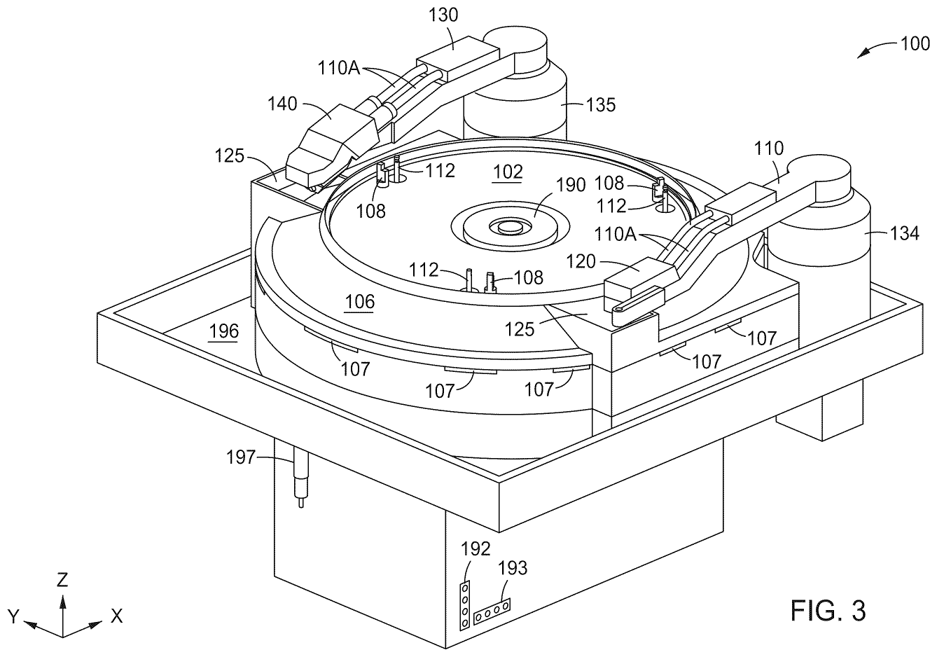

The processing chamber 100 includes a process rotor 102, collection rotor 104 rotor cover 106, first sweep arm 110 (FIG. 3), enclosure 118, first nozzle mechanism 120 (FIG. 3), second sweep arm 130, second nozzle mechanism 140, plenum 151, primary exhaust 160, secondary exhaust 171, an air intake 180, and underside nozzle mechanism 190. In one or more embodiments, a controller 170 may control the functionality of the processing chamber 100.

The process rotor 102 includes a plurality of stand-off pins 108 extending from a top surface thereof. According to embodiments, three stand-off pins 108 are provided on the process rotor 102. The stand-off pins 108 are configured to support a substrate 150 that is delivered to the processing chamber 100 by a substrate handler such as, for example, a robot arm. Accordingly, the stand-off pins 108 may be evenly positioned around a circumference of the process rotor 102. The stand-off pins 108 may have an “L” shaped upper profile to provide support the substrate 150 and to ensure the substrate 150 is centrally positioned on the process rotor 102. The stand-off pins 108 may also have a minimal cross-section so as to have minimal contact points with the substrate 150 being supported.

The process rotor 102 also includes a plurality of grip pins 112. The grip pin 112 extends from a hole in the top surface of the process rotor 102. A protruding element extends from a lower portion of the grip pin 112 through a hole in a side surface of the process rotor 102. According to embodiments, the grip pin 112 is movable between a grip position and a release position.

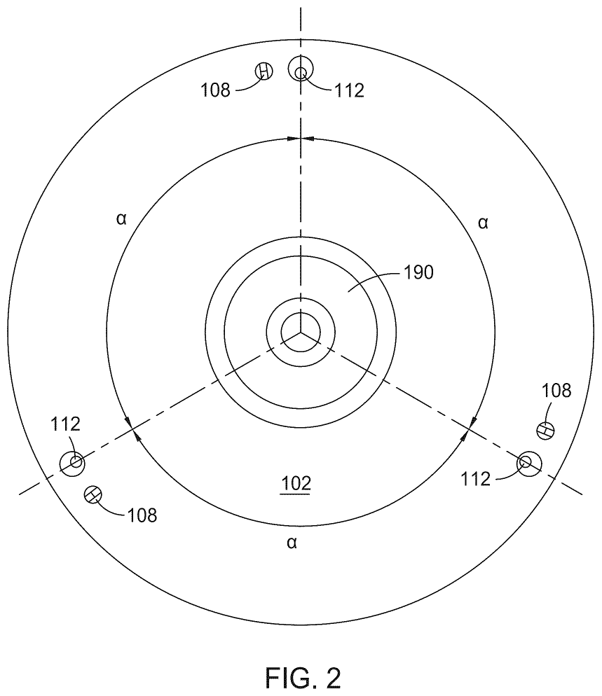

The grip pins 112 may grip, or hold, the substrate 150 during the cleaning process. FIG. 2 is a top view of the process rotor 102 with an example arrangement of the grip pins 112 and stand-off pins 108, according to one or more embodiments. According to one or more embodiments, the grip pins 112 may be evenly arranged around the top surface of the process rotor 102 at an angle α relative to one another as measured in a plane that is generally parallel to the top surface of the process rotor 102 (e.g., X-Y plane). The angle α that is, the angular position of the grip pins 112 from each other, may be approximately 120°. Alternatively, the grip pins 112 may be oriented less than 120° from each other or greater than 120° from each other. Further, the total number of grip pins 112 may be three or more. Alternatively, the total number of grip pins 112 is four or more. The grip pins 112 may have minimal contact with the substrate 150 along the edge of the substrate 150 such that the grip pins 112 do not collect a significant amount of a fluid at a contacting interface and impede the cleaning process of the substrate 150.

Referring back to FIG. 1, the process rotor 102 is movable between a raised position and a lowered position by use of a lift assembly 127 that includes a second drive motor 128 and a shaft 124. In the raised position, the process rotor 102 can receive the substrate 150, as the stand-off pins 108 and the grip pins 112 are above a top portion of the collection rotor 104 and the rotor cover 106. When the process rotor 102 is moved to the lowered position the grip pins 112 rotate to the grip position that causes the substrate to be retained between the grip pins 112. The lowered position is also referred to herein as the processing position at which the cleaning and drying process is performed.

As noted above, the collection rotor 104 includes the annular inner surface 114 The annular inner surface 114 defines a processing volume 116 within the processing chamber 100. For example, the substrate 150 may be cleaned within the processing volume 116. Further, the annular inner surface 114 has an angled portion that is symmetric about a rotational axis 126 of the process rotor 102 and the collection rotor 104.

A first drive motor 122 may be coupled to the process rotor 102 via the shaft 124. The first drive motor 122 rotates the process rotor 102 and the collection rotor 104 about the rotational axis 126. That is, the controller 170 may control the first drive motor 122 to rotate the process rotor 102 and the collection rotor 104 at various rotational speeds set by process recipes contained a memory 174 of the controller 170. The first drive motor 122 may be referred to as a rotation motor. The process rotor 102 and the collection rotor 104 may be rotationally fixed relative to each other, i.e., configured to rotate together.

Further, the second drive motor 128 may also be coupled to the process rotor 102 via the shaft 124. The second drive motor 128 may impart linear motion to the process rotor 102 along the rotational axis 126 by use of a ball-screw assembly that is configured to create linear motion of the process rotor 102 due to relative rotational motion created by the second drive motor 128 rotating the shaft 124 relative to a portion of the collection rotor 104. That is, the controller 170 may control the second drive motor 128 to move the process rotor 102 in the Z direction between the raised position and lowered position. In addition, the second drive motor 128 may be used to move the process rotor 102 in the Z direction in preparation for, or during, a cleaning, rinsing, and/or drying process to precisely position the substrate 150 at a desired distance from first and second nozzle mechanisms 120, 140 or position relative to the surface of the collection rotor 104. Thus, the second drive motor 128 may be configured to move the process rotor 102 in the Z direction while the process rotor 102 is spinning and/or while the substrate 150 is being subject to cleaning, rinsing, and/or drying. The second drive motor 128 may be referred to as a linear actuator. Further, the second drive motor 128 may be one of a hydraulic, pneumatic, electro-mechanical, and a magnetic motor. The linear movement of the process rotor 102 may be independent of movement of the collection rotor 104.

The grip pins 112 hold the substrate 150 when the process rotor 102 is in the lowered position, as described above. When the process rotor 102 is in the lowered position, the first drive motor 122 may rotate the process rotor 102 while cleaning fluids are applied to the substrate 150 for cleaning. Cleaning fluids may be applied to an upper surface of the substrate 150 by the first nozzle mechanism 120 and the second nozzle mechanism 140, and to a lower surface of the substrate 150 via the underside nozzle mechanism 190, while the process rotor 102 and the collection rotor 104 are rotated. Because the collection rotor 104 is rotated with the process rotor 102, backsplash of the cleaning fluids against the annular inner surface 114 may be mitigated.

In one or more embodiments, the processing chamber 100 includes the underside nozzle mechanism 190. Cleaning and/or rinsing fluids may be delivered to the underside nozzle mechanism 190 via the shaft 124, which is coupled to a fluid source 123. In one or more embodiments, cleaning and/or rinsing fluids may flow onto a backside of substrate 150 through the underside nozzle mechanism 190. The cleaning and/or rinsing fluids may be a rinsing agent (e.g., de-ionized water or ozonated water) or a cleaning chemical. Further, the cleaning and/or rinsing fluids may be provided from the fluid source to the underside nozzle mechanism 190 via the shaft 124.

The process rotor 102 may include a drain 191 adjacent the underside nozzle mechanism 190 to allow fluid applied to the backside of substrate 150 to drain (described below). According to embodiments, the drain 191 may be an annulus arranged circumferentially around underside nozzle mechanism 190. The drain 191 feeds through shaft 124 to an aspirate connection (not shown), which may apply a negative pressure to the drain 191 to ensure complete drainage of fluid. It is contemplated that in one or more embodiments, the underside nozzle mechanism 190 may be omitted from the processing chamber 100.

Referring to FIG. 3, a first sweep arm motor 134 may be coupled to the first sweep arm 110. The first sweep arm motor 134 is configured to move the first sweep arm 110 in an arcuate path that is parallel to a surface of the substrate 150, during the cleaning process, such that the cleaning fluids output by the first nozzle mechanism 120 are evenly distributed over the surface of the substrate 150. The first sweep arm motor 134 may also be configured to move the first sweep arm 110 axially to set a distance between the first nozzle mechanism 120 and the surface of the substrate 150. For example, the first sweep arm motor 134 may include an air cylinder for raising and lowering the first nozzle mechanism 120.

Similarly, a second sweep arm motor 135 may be coupled to the second sweep arm 130. The second sweep arm motor 135 is configured to move the second sweep arm 130 in an arcuate path that is parallel to a surface of the substrate 150, during the cleaning process, such that the cleaning fluids output by the second nozzle mechanism 140 are evenly distributed over the surface of the substrate 150. The second sweep arm motor 135 may also be configured to move the second sweep arm 130 axially to set a distance between the second nozzle mechanism 140 and the surface of the substrate 150. For example, the second sweep arm motor 135 may include an air cylinder for raising and lowering the second nozzle mechanism 140.

The first and second sweep arms 110, 130 may each include one or more tubes to deliver fluids to the first and second nozzle mechanisms 120, 140, respectively. According to an embodiment, the first and second sweep arms 110, 130 each include connections 110A for delivering fluids and/or electrical signals (e.g., control signals) to the first and second nozzle mechanisms 120, 140, respectively. For example, water and isopropyl alcohol (IPA) may be separately delivered to the first and second nozzle mechanisms 120, 140 via connections 110A. For example, the first and second sweep arms 110, 130 may also each include a connection 110A for supplying control signals from the controller 170 to the first and second nozzle mechanisms 120, 140, respectively.

The first and second nozzle mechanisms 120, 140 may each include one or more non-contact cleaning or drying technologies. Each of the first and second nozzle mechanisms 120, 140 may have one, two, three or more nozzles that each may output a media that is any combination of liquid or gas. One or more of the first and second nozzle mechanisms 120, 140 may be a megasonic nozzle, fluid jet nozzle, mist nozzle, high pressure nozzle, or a kinetic energy nozzle. The megasonic nozzle includes one or more elements, such as a piezoelectric element, configured to alternatively apply compression and rarefraction to the cleaning fluid in an alternating fashion according to a sinusoidal or other pattern to generate a megasonic actuated fluid. For example, the megasonic nozzle may be configured to alternatively applying compression and rarefraction in a sinusoidal pattern at a rate of 950 kHz to generate the megasonic actuated fluid. Alternatively, other frequencies may be used.

According to an embodiment, where one of the first and second nozzle mechanisms 120, 140 is a megasonic nozzle, the other of the first and second nozzle mechanisms 120, 140 may be configured to apply a chemical cleaning agent, a rinsing agent (e.g., DI water), and/or a drying agent (e.g., IPA vapor). For example, according to the embodiment illustrated in FIG. 3, first nozzle mechanism 120 may be a drying nozzle configured to apply a drying agent such as isopropyl alcohol (IPA) and/or de-ionized water, and second nozzle mechanism 140 may be a megasonic nozzle that is configured to provide de-ionized water and megasonic energy to the surface of the substrate during processing. In some configurations, the second nozzle mechanism 140 may also be configured to apply a chemical cleaning agent, a rinsing agent, and/or a drying agent

As noted, the cleaning, rinsing, and/or drying fluids may be provided to the first and second nozzle mechanisms 120, 140 via connections 110A. The number of connections may be based on the number of nozzles within the nozzle mechanism being used and/or the number of different types of cleaning chemical, rinsing agents and/or drying agents utilized by the first and second nozzle mechanisms 120, 140. For example, where the first and second nozzle mechanisms 120, 140 are each configured to output two different cleaning fluids, two different connections 110A may be utilized for each first and second nozzle mechanisms 120, 140. Further, the flow rate of the different cleaning chemistries and/or rinsing agents through different nozzles may be varied. For example, the flow rate of a cleaning chemical, rinsing agent or drying agent from a first one of the nozzles may be different than the flow rate of a cleaning chemical, rinsing agent or drying agent from a second one of the nozzles. Alternatively, the flow rate of a cleaning chemical, rinsing agent or drying agent from at least one of the nozzles may be varied during a cleaning process, a rinsing process, and/or a drying process. The first and second sweep arms 110, 130 may include a coupling arrangement for fastening the first and second nozzle mechanisms 120, 140 thereto, respectively.

The path of the first and second sweep arms 110, 130 during a cleaning process may be an arcuate path that is parallel to a front surface of the substrate 150. Alternatively, other shapes and/or lengths of paths may be utilized. For example, the range of motion of the first and second sweep arms 110, 130 may be varied. According to some embodiments, the first and second nozzle mechanisms 120, 140 respectively coupled to the end of first and second sweep arms 110, 130 may pass over the center of the substrate 150 in an arcuate path. The position of the first and second sweep arms 110, 130 and/or the first and second nozzle mechanisms 120, 140 may be adjusted to ensure that the first and second nozzle mechanisms 120, 140 passes over the center of a rotating substrate 150 during processing. Further, the nozzle mechanisms 120, 140 may be moved relative to the corresponding first and second sweep arms 110, 130 to vary the position of the first and second nozzle mechanisms 120, 140 relative to surface of the substrate 150. Further, the axial distance between first and second nozzle mechanisms 120, 140 and the surface of the substrate 150 may be varied to aid in the cleaning process.

The first and second nozzle mechanisms 120, 140 may include a mass flow controller to provide mass flow control of fluids being sprayed on the substrate 150, depending on a desired cleaning, rinsing, and/or drying process. The nozzle mechanisms 120, 140 may also include a vaporizer for vaporizing IPA or water being sprayed on the substrate 150, depending on a desired cleaning, rinsing and/or drying process. The nozzle mechanisms 120, 140 may also be configured to blow air only, depending on a desired cleaning process. For example, the cleaning, rinsing, and/or drying process may optionally include a cycle in which one or both of the nozzle mechanisms 120, 140 blow air to dry the stand-off pins 108 and the grip pins 112.

Referring to FIG. 1, the enclosure 118 may cover the processing chamber 100, i.e., defining an interior volume 185 of the processing chamber 100. Alternatively, the processing chamber 100 may be “open” to the rest of the cluster tool, i.e., the process chamber alternatively does not include an enclosure 118. In such an alternative embodiment, the face of the substrate 150 is exposed to atmosphere while being processed within the processing chamber 100.

According to embodiments with the enclosure 118 covering the processing chamber 100, doors 119A, 119B may selectively open to provide access to the interior volume 185 of the processing chamber 100 for inserting or removing the substrate 150 from the processing chamber 100. In one or more embodiment, during cleaning processing the doors 119A, 119B are closed to seal the processing chamber 100. When both doors 119A, 119B are closed, the interior volume 185 of the processing chamber 100 may be isolated from the remainder of the cluster tool, such that, for example fumes, liquids or particles generated and/or used elsewhere in the cluster tool do not enter the processing chamber 100 during the cleaning process. Similarly, any fumes or liquids used and/or generated during the cleaning process in the processing chamber 100 are removed from the processing chamber 100 in a controlled manner via the primary exhaust 160 and/or the secondary exhaust 171 so as to prevent fumes, liquids or particles generated and/or used during cleaning processing in the processing chamber 100 from building up and depositing debris within the internal volume. The processing chamber 100 is in a substrate processing configuration when both doors 119A, 119B are closed and the process rotor 102 is in the processing position with the grip pins 112 holding the substrate 150.

The enclosure 118 may also include one or more sensors 194. The one or more sensors 194 may include one or more optical sensors such as one or more cameras. The one or more sensors 194 are configured to detect one or more components within the interior volume 185 of the processing chamber 100. For example the one or more sensors 194 can be positioned to detect the substrate, the first nozzle mechanism 120, the second nozzle mechanism 140, the rotor cover 106, the plurality of stand-off pins 108, or a combination thereof. In one or more embodiments, the one or more sensors are operated by the controller 170. The enclosure may also include ion bars 198 or the like to prevent static charge buildup in the interior of the processing chamber 100.

The primary exhaust 160 and/or the secondary exhaust 171 may be utilized to remove excess moisture and/or all fluids from the processing chamber 100 during and/or after a cleaning cycle. In one embodiment, moisture flows through drain holes 195B and into the primary exhaust 160. For example, as the substrate 150 is rotated, the drain holes 195B are configured to ensure that moisture does not collect on the substrate 150 and is removed via the primary exhaust 160. In one embodiment, one or more O-rings or other sealing members may be positioned where the primary exhaust 160 meets the enclosure 118. The process chamber may have two primary exhausts 160, one on each lateral side of the processing chamber 100. Likewise, the processing chamber 100 may have two secondary exhausts 171, one on each lateral side of the processing chamber 100.

According to an embodiment, the door 119A may be on a side of the enclosure 118 facing a cluster tool. Additionally, the door 119B may be on a side of the enclosure 118 facing an interior of the cluster tool. During a substrate loading process, door 119B is opened such that substrate 150 may be inserted into the processing chamber 100, while door 119A is closed to isolate the interior of the processing chamber 100. The processing chamber 100 is in a substrate loading configuration when door 119A is closed, door 119B is open, process rotor 102 is in the raised position, and the grip pins 112 are in the release position.

Further, during a substrate unloading process, the door 119A is opened such that the substrate 150 may be extracted from the processing chamber 100, while the door 119B is closed to continue to isolate the processing chamber 100. The processing chamber 100 is in a substrate unloading configuration when the door 119A is open, the door 119B is closed, the process rotor 102 is in the raised position, and the grip pins 112 are in the release position.

Positive air flow through the interior volume 185 and processing volume 116 may be provided by a fan/filter unit (FFU) 142. The FFU 142 may be connected to the enclosure 118, for example. The FFU 142 includes the air intake 180 and the plenum 151. The air intake 180 may include, for example, a HEPA filter and a fan. Air flows from the air intake 180, through the plenum 151, into the interior volume 185 and processing volume 116, and out the primary exhaust 160 and the secondary exhaust 171.

An annular collection weir 195 may be formed below an outer portion of the collection rotor 104. The primary exhaust 160 is connected to the collection weir 195. An annular space 195A is defined between an outer surface of the collection rotor 104 and an inner surface of the rotor cover 106. Accordingly, air provided by the FFU 142 can also flow through the annular space 195A, into the collection weir 195, and out the primary exhaust 160. According to embodiments, this configuration may allow for a high volume of laminar air flow through the annular space 195A between the rotor cover 106 and the collection rotor 104, which may reduce the amount of residual vapors and liquid droplets created during processing and disposed within this region, and thus reduce substrate contamination and improve the cleaning process. Additionally, any liquid that may inadvertently be introduced into the annular space 195A can drain out the primary exhaust 160, assisted by the air flow through the annular space 195A.

A plurality of drain holes 195B may be formed in a base of the collection rotor 104. For example, according to embodiments, the drain holes 195B may be formed near the annular inner surface 114 of the collection rotor 104. The drain holes 195B allow fluids applied during a cleaning process of a substrate 150 to drain out of the collection rotor 104 and into the collection weir 195. According to an embodiment, the annular inner surface 114 of the collection rotor 104 includes a portion angled inward with respect to vertical from a lower portion to an upper portion. This configuration may improve fluid drainage from the processing volume 116 due to rotation of the collection rotor 104. According to some embodiments, the plurality of drain holes 195B are configured to enable a laminar flow of air to flow over the surface of a substrate and through the inner region of the collection rotor 104 and drain holes 195B to reduce the amount of residual vapors and liquid droplets created during processing and disposed within this region, and thus reduce substrate contamination and improve the cleaning process. Additionally, air provided by the FFU 142 can also flow through the processing volume 116, into the drain holes 195B, into the collection weir 195, and out the primary exhaust 160. According to embodiments, this configuration may provide for a high volume of air flow through the processing volume 116, which may provide for improved cleaning processing.

Additionally, according to some embodiments, the collection rotor 104 may include rotor extension 115 extending diagonally downward and outward from the lower portion of the collection rotor 104. The rotor extension 115 (FIG. 1) may further improve fluid drainage from the processing volume by drawing and guiding the fluids from the drain holes 195B as the collection rotor 104 rotates. The rotor extension 115 is generally configured to extend past the outer edge of the drain holes 195B and past the outer diameter of the collection rotor at the level of the drain holes 195B.

The rotor cover 106 includes a plurality of vent openings 107 (FIG. 1) and annular duct 107A that are used to evacuate regions of the interior volume 185. Each of the plurality of vent opening 107 connects the interior volume 185 to the annular duct 107A. The secondary exhaust 171 is connected to the annular duct 107A via a channel (not shown) formed in the drain pan 196. Accordingly, air provided by the FFU 142 can flow through the vent openings 107, into the annular duct 107A of the rotor cover 106, and out the secondary exhaust 171. According to embodiments, this configuration may provide for a high volume of air flow through the perimeter of the rotor cover 106 and into the vent openings 107, which reduce the amount of residual gases and vapors created during processing and disposed within this outer region of the processing chamber 100. The residual vapors and gases can include IPA vapors, water vapor and/or cleaning chemistry vapors created or dispensed into the interior volume 185 during processing. In some embodiments, the secondary exhaust 171 can be coupled to a scrubbed exhaust that is adapted to remove residual gases and vapors, which can be important to remove vapors that have an airborne permissible exposure limit (PEL), lower explosive limit (LEL) and/or upper explosive limit (UEL), such as IPA. Additionally, any liquid that may inadvertently be introduced into the annular duct 107A can drain out the secondary exhaust 171, assisted by the air flow through the annular duct 107A.

The plenum 151 may be configured to control the air flow within the processing chamber 100 to minimize re-circulation. For example, the plenum 151 may increase and/or decrease the amount of air flowing into the processing chamber 100 to minimize re-circulation. The air flow re-circulation can be minimized due to, for example, the configuration of the collection rotor 104, the rotor cover 106, the vent openings 107, the annular duct 107A, the collection weir 195, the primary exhaust 160, the secondary exhaust 171, and the air intake 180 disclosed herein.

In one embodiment, during the cleaning process, uniform air flow across the surface of the substrate 150 is primarily generated by the primary exhaust 160 and the plenum 151. In various embodiments, the primary exhaust 160 is configured to provide a path for air to flow out of the processing chamber 100 to prevent particles from reattaching to the surface of the substrate 150. As is described above, air may be provided to the plenum 151 by the air intake 180, and exhausted from the processing chamber 100 by the primary exhaust 160 and the secondary exhaust 171. The plenum 151 may be a shower head style plenum. Further, the geometry of the primary exhaust 160, the shape of the collection rotor 104, the shape of the rotor cover 106, and/or the shape of the collection weir 195 may be optimized to reduce re-circulation within the processing chamber 100. Reducing re-circulation at least minimizes re-attachment of particles and any vaporized cleaning fluids on the substrate. The geometry of the collection rotor 104, the rotor cover 106, and the collection weir 195 may define the annular volume, which may be optimized to minimize re-circulation. Further, primary exhaust 160 and secondary exhaust 171 provide paths for the cleaning fluids and rinsing fluids to be removed from the processing chamber 100, minimizing re-circulation within the processing chamber 100. The plenum 151 may be positioned proximate the first and second nozzle mechanisms 120, 140, and the substrate 150 may be positioned between the plenum 151 and the primary exhaust 160.

In one or more embodiments, the rotor cover 106 includes two nozzle cups 125 (FIG. 3) respectively positioned on opposite sides of the top surface of the rotor cover 106. The nozzle cups 125 are each configured and positioned to receive one of the nozzle mechanisms 120, 140. That is, when the first nozzle mechanism 120 is not in use, such as, for example, when the processing chamber 100 is in the substrate loading or unloading configuration during transfer of a substrate 150 into or out of the processing chamber 100 or when a current cleaning processing step does not require use of the first nozzle mechanism 120, the first sweep arm motor 134 positions the first sweep arm 110 so that the corresponding first nozzle mechanism 120 is positioned in one of the nozzle cups 125. Similarly, when second nozzle mechanism 140 is not in use, such as, for example, when the processing chamber 100 is in the substrate loading or unloading configuration during transfer of a substrate into or out of the processing chamber 100 or when a current cleaning processing step does not require use of second nozzle mechanism 140, the second sweep arm motor 135 positions the second sweep arm 130 so that the corresponding second nozzle mechanism 140 is positioned in the other one of the nozzle cups 125.

The controller 170, such as a programmable computer, is connected to elements of processing chamber 100 and is configured to operate the elements of the processing chamber 100. For example, the controller 170 may control the loading, unloading and cleaning of substrates 150 by the processing chamber 100.

In one or more embodiments, the controller 170 is configured to receive data or input as sensor readings from the one or more sensors 194. The controller 170 includes a central processing unit (CPU) 172 (e.g., one or more processors), the memory 174 containing instructions, and support circuits 176 for the CPU 172. The controller 170 controls various items directly, or via other computers and/or controllers. In one embodiment which can be combined with other embodiments, the controller 170 is communicatively coupled to dedicated controllers, and the controller 170 functions as a central controller.

The controller 170 is one or more of any form of a general-purpose computer processor that is used in an industrial setting for controlling various substrate processing chambers and equipment, and sub-processors thereon or therein. The memory 174, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 176 of the controller 170 are coupled to the CPU 172 for supporting the CPU 172. The support circuits 176 include cache, power supplies, clock circuits, input/output circuitry and subsystems, and the like. Operational parameters and operations are stored in the memory 174 as a software routine that is executed or invoked to turn the controller 170 into a specific purpose controller to control the operations of the various chambers/modules described herein. The controller 170 is configured to conduct any of the operations described herein. The instructions stored on the memory, when executed, cause one or more of the operations (such as the operations of the method 500) described herein to be conducted in relation to the processing chamber 100. The controller 170 and the processing chamber 100 are at least part of a system for processing substrates.

The various operations described herein can be conducted automatically using the controller 170, or can be conducted automatically or manually with certain operations conducted by a user.

The controller 170 is configured to control power to at least the process rotor 102, the plurality of stand-off pins 108, the first sweep arm 110, second sweep arm 130, the first nozzle mechanism 120, the second nozzle mechanism 140, the one or more sensors 194, or a combination thereof.

The controller 170 is configured to adjust the output to the controls based on the sensor readings, a system model, and stored readings and calculations. The controller 170 includes embedded software and a compensation algorithm to calibrate measurements. The controller 170 can include one or more machine learning algorithms and/or artificial intelligence algorithms that detect errors (such as fluid dripping, substrate 150 displacement, fluid splashing, and/or wafer dryout) for the processing operations.

The one or more machine learning algorithms and/or artificial intelligence algorithms may implement, adjust and/or refine one or more algorithms, inputs, outputs or variables described herein. Additionally or alternatively, the one or more machine learning algorithms and/or artificial intelligence algorithms may rank or prioritize certain aspects of adjustments of the processing chamber 100 and/or method(s) relative to other aspects of the processing chamber 100 and/or method(s) (such as the method 500). The one or more machine learning algorithms and/or artificial intelligence algorithms may account for other changes within the processing systems such as hardware replacement and/or degradation. In one or more embodiments, the one or more machine learning algorithms and/or artificial intelligence algorithms account for upstream or downstream changes that may occur in the processing system due to variable changes of the processing chamber 100 and/or method(s). For example, if variable “A” is adjusted to cause a change in aspect “B” of the process, and such an adjustment unintentionally causes a change in aspect “C” of the process, then the one or more machine learning algorithms and/or artificial intelligence algorithms may take such a change of aspect “C” into account. In such an embodiment, the one or more machine learning algorithms and/or artificial intelligence algorithms embody predictive aspects related to implementing the processing chamber 100 and/or the method(s). The predictive aspects can be utilized to preemptively mitigate unintended changes within a processing system.

The one or more machine learning algorithms and/or artificial intelligence algorithms can use, for example, a comparison model to detect errors. The algorithm can be unsupervised or supervised. The one or more machine learning algorithms and/or artificial intelligence algorithms can detect, for example, processing errors such as fluid dripping from the first nozzle mechanism 120, fluid dripping from the second nozzle mechanism 140, substrate 150 displacement, fluid splashing, and/or substrate 150 dry out.

In one or more embodiments, the controller 170 automatically conducts the operations described herein without the use of one or more machine learning algorithms and/or artificial intelligence algorithms. In one or more embodiments, the controller 170 compares measurements (such as readings and/or signal from the one or more sensors 194) to data in a look-up table and/or a library to identify processing errors and/or adjust one or more processing parameters. In one or more embodiments, the controller 170 stops the processing operation when one or more errors are detected. The controller 170 can stored measurements as data in the look-up table and/or the library.

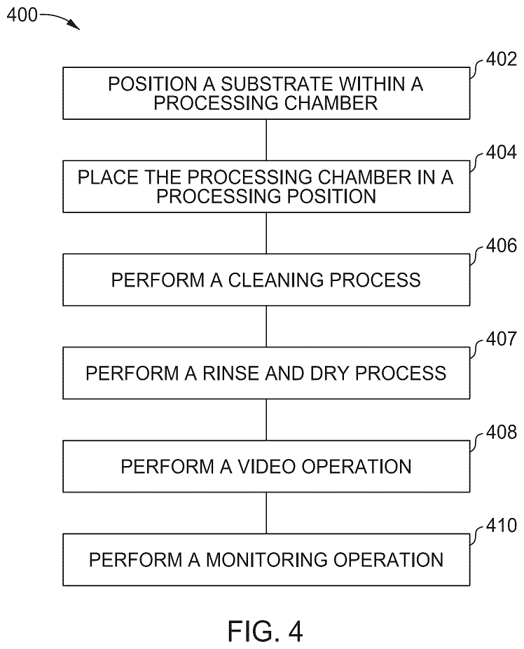

FIG. 3 is a top isometric view of the processing chamber 100 with the enclosure 118 omitted, according to one or more embodiments. FIG. 4 is a bottom isometric view of the processing chamber 100, also with the enclosure 118 omitted, according to one or more embodiments. It is intended that all cleaning liquids applied during a cleaning processing are contained within the collection rotor 104 and the rotor cover 106 and drained through the primary exhaust 160 and/or the secondary exhaust. 170. However, cleaning liquids may inadvertently leak outside of the collection rotor and the rotor cover 106 due to, for example, failure or defect in one or more components. Accordingly, to prevent contamination of the exterior of the processing chamber 100 in case of an inadvertent leak, a drain pan 196 is provided surrounding the perimeter of the rotor cover 106. An interior surface of drain pan 196 can be seen in FIG. 3 and an exterior surface of drain pan can be seen in FIG. 4. A leak detect sensor 197 may also be positioned in the base of the drain pan 196. The leak detect sensor 197 may provide an alert to an operator in the event that a leak is detected in the drain pan 196.

According to some embodiments, the footprint of the processing chamber 100 in the X-Y plane is substantially square or rectangular. In some embodiments, the processing chamber 100 may be sized to perform cleaning processing on a 300 mm diameter substrate 150 while having a footprint of approximately 550 mm×550 mm. In some embodiments, a longest side of the processing chamber 100 may be less than approximately twice the diameter of the substrate 150. In some embodiments, an overall height of the processing chamber 100 may be approximately 500 mm. In some embodiments, an overall height of the processing chamber 100 may be less than approximately one and two thirds times the diameter of the substrate 150. A conventional cleaning module may need a relatively large size to provide sufficient internal volume in order to properly ventilate the interior during cleaning processing. In contrast, the processing chamber 100 according to embodiments disclosed herein can be relatively small to allow multiple processing chamber 100 to be stacked and/or reduce the footprint of the cluster tool. The relatively small size may be due to, for example, the high rate of air flow from the air intake 180 through the processing chamber 100 and out the primary and secondary exhausts 160, 171.

The processing chamber 100 may include one or more inlet connections 192. The inlet connections 192 provide a path for the cleaning fluids to be provided to the processing chamber 100 during a cleaning process. The cleaning fluids may be provided to, for example, the first nozzle mechanism 120, second nozzle mechanism 140, the underside nozzle mechanism 190, and/or the fluid source 123. Further, the processing chamber 100 may include electrical connections 193 configured to couple to power and/or communication cables external to the processing chamber 100.

FIG. 4 is a schematic block diagram of a method 400 of processing a substrate, according to one or more embodiments. The method 400 can be conducted in the processing chamber 100, or other processing chambers.

At operation 402 of method 400, a substrate 150 is positioned within the processing chamber 100. In one or more embodiments, the processing chamber 100 is disposed within a cluster tool. In one or more embodiments, a robotic arm inserts a substrate 150 through the open door 119B such that the substrate 150 rests on the stand-off pins 108. After the substrate 150 has been fully inserted into the processing chamber 100 and loaded onto the stand-off pins 108, the robotic arm releases the substrate 150 and is retracted from the processing chamber. In one or more embodiments, the controller 170 provides instructions to the robotic arm to place the substrate 150 on the stand-off pins 108 and then retract.

At operation 404 of the method 400, the processing chamber is placed in a processing position. In one or more embodiments, operation 404 includes activating the second drive motor 128 to lower the process rotor 102 to the lowered position. The grip pins 112 are rotated to the gripping position to grip the substrate 150. The grip pins 112 help align the substrate 150 with the axis of rotation. In one or more embodiments, the controller 170 provides instructions to perform operation 404 to the processing chamber 100.

At operation 406 of method 400, a cleaning process is performed on the substrate on the substrate 150. In one or more embodiments, operation 406 includes rotating the first drive motor 122, the process rotor 102, and the collection rotor 104 at a predetermined rotational speed. In one or more embodiments, the second sweep arm motor 135 rotates the second sweep arm 130 and second nozzle mechanism 140 through a predetermined angle sweep over the substrate 150 held on the process rotor 102 by the grip pins 112. Additionally, the second drive motor 128 and/or the second sweep arm motor 135 may also adjust a distance in the Z direction between the second nozzle mechanism 140 and the upper surface of the substrate 150 to a predetermined distance. Additionally, for example and as described above, the second nozzle mechanism 140 applies a megasonic cleaning fluid to the upper surface of the substrate 150 while the substrate 150 is rotated by the process rotor 102 and while the second sweep arm 130 is rotated through the predetermined angle sweep. When the cleaning process is complete, the second sweep arm motor 135 rotates the second sweep arm 130 so that the second nozzle mechanism 140 is positioned in its corresponding nozzle cup 125. In one or more embodiments, the controller 170 may provide instructions to the first drive motor 122, the second drive motor 128, the second sweep arm motor 135, and/or the second nozzle mechanism 140 in connection with performing the cleaning process on the substrate 150.

At operation 407 of method 400, the processing chamber 100 performs a final rinse and dry process on the substrate 150. In one or more embodiments, the first drive motor 122 continues to rotate the process rotor 102 and the collection rotor 104 at a predetermined rotational speed. Additionally, for example and as described above, the first sweep arm motor 134 rotates the first sweep arm 110 and first nozzle mechanism 120 through a predetermined angle sweep over the substrate 150 held on the process rotor 102 by the grip pins 112. Additionally, for example and as described above, the second drive motor 128 and/or the first sweep arm motor 134 may also adjust a distance in the Z direction between the first nozzle mechanism 120 and the upper surface of the substrate 150 to a predetermined distance. Additionally, for example and as described above, the first nozzle mechanism 120 applies a rinsing and/or drying fluid to the upper surface of the substrate 150 while the substrate 150 is rotated by the process rotor 102 and while the first sweep arm 110 is rotated through the predetermined angle sweep. For example, application of the rinsing and/or drying fluid may include applying de-ionized water to the substrate 150. For example, application of the rinsing and/or drying fluid may also include applying vaporized IPA. According to some embodiments, applying de-ionized water and vaporized IPA are provided simultaneously or sequentially. According to some embodiments, the vaporized IPA is delivered to positions that are inboard (i.e., closer to the substrate center) of the position of the DI water as the two nozzles are moved from the center to the edge of the substrate.

After a predetermined time and/or after a predetermined amount of rinsing and/or drying fluid are applied by the first nozzle mechanism 120 to the substrate 150, the first nozzle mechanism 120 stops applying the rinsing and/or drying fluid, and the substrate 150 continues to be rotated by the process rotor 102 at a predetermined rotational speed for a predetermined time. For example, while no further fluids are being applied to the substrate 150, the process rotor 102 rotates at approximately 2,000 RPM for a predetermined time. Due to rotation of the process rotor 102 and collection rotor 104, fluids applied to the substrate 150 are urged towards the annular inner surface 114 of collection rotor 104 and then through drain holes 195B and into the collection weir 195. The collected fluids and air supplied from the FFU 142 are then pulled into primary exhaust 160 for exhaust processing. When the final rinse and dry process is complete, the first sweep arm motor 134 rotates the first sweep arm 110 so that the first nozzle mechanism 120 is positioned in its corresponding nozzle cup 125. Additionally, the first drive motor 122 stops rotating the process rotor 102 and the collection rotor 104. In one or more embodiments, the controller 170 provides instructions to the first drive motor 122, the second drive motor 128, the first sweep arm motor 134, and/or the first nozzle mechanism 120 in connection with performing the final rinse and dry process on the substrate 150.

At operation 408 of method 400, a video operation is performed. In one or more embodiments, the video operation is performed by the one or more sensors 194. In one or more embodiments the one or more sensors 194 are optical sensors, such as a camera, such as a video camera. The one or more sensors 194 capture an image or a video of one or more components within the processing chamber. The one or more sensors 194 transmit the video as a video signal to the controller 170.

It is contemplated that operation 408 may be performed prior to operations 406 and/or 407, simultaneously to operation 406 and/or 407, or after operation 406 and/or 407. In one or more embodiments, operation 408 is repeated continuously while performing the method 400.

At operation 410 of method 400, a monitoring operation is performed. In one or more embodiments, the monitoring operation is performed by the controller 170. At operation 410, the controller 170 revises the video signal transmitted from the one or more sensors 194. The controller 170 analyzes one or more components within the video signal and performs at least one of sub-methods 500 in order to determine the presence of errors within the processing chamber 100.

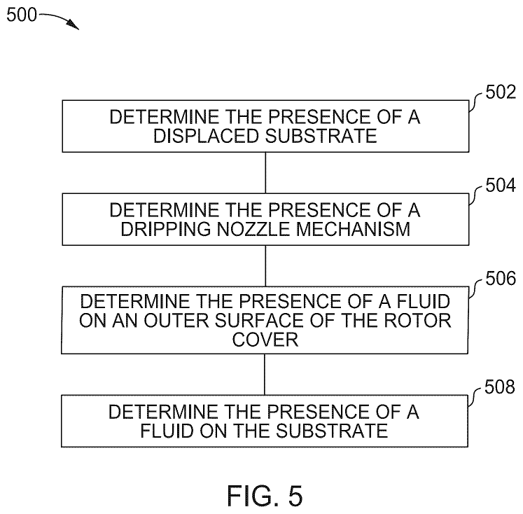

FIG. 5 is a schematic block diagram of the one or more sub-methods 500 performed by the controller 170 when analyzing the one or more components within the video signal in order to determine the presence of errors within the processing chamber 100, according to one or more embodiments. The one or more sub-methods 500 include sub-method 502, sub-method 504, sub-method 506, and sub-method 508. Sub-method 502 includes determining the presence of a displaced substrate. Sub-method 504 includes determining the presence of a dripping nozzle mechanism. Sub-method 506 includes determining the presence of a fluid on an outer service of the rotor cover. Sub-method 508 includes determining the presence of a fluid on the substrate.

In one or more embodiments, while performing operation 410, the controller 170 performs sub-method 502. Sub-method 502 includes determining the presence of a displaced substrate. The substrate 150 may become displaced at any point while performing the method 400, which can negatively affect substrate processing. The controller 170 determines whether or not the substrate is displaced by analyzing the stand-off pins 108, grip pins 112, the outer edge of the outer edge of the substrate 150, or a combination thereof.

In one or more embodiments, when the substrate 150 becomes displaced, it covers one or more of the stand-off pins 108 and/or grip pins 112. In one or more embodiments, the controller 170 tracks the number of stand-off pins 108 and/or grip pins 112 visible within the video signal to determine a detected number of pins (i.e., not covered by the substrate 150). The controller 170 compares the detected number of pins within the video signal to a desired number of visible stand-off pins 108 and/or grip pins 112 stored within the memory 174 of the controller 170 (i.e., stand-off pins 108 and/or grip pins 112 that should be visible). If the controller 170 determines that the actual number of visible stand-off pins 108 and/or grip pins 112 is different from the desired number of visible stand-off pins 108 and/or grip pins 112 stored within the memory 174 of the controller 170, the controller determines that the substrate 150 has become displaced within the processing chamber 100. If the controller 170 determines that substrate 150 has become displaced within the processing chamber 100 then the controller 170 generates an error message. If the controller 170 generates an error message then the controller 170 stops the method 400.

In one or more embodiments, the controller 170 tracks the position of the stand-off pins 108 and/or the grip pins 112. In one or more embodiments, the controller 170 analysis the position of one or more stand-off pins 108 and/or grip pins 112 in a first frame of the video signal. The controller 170 assigns each detected stand-off pin 108 and/or grip pin 112 a unique identifier. The controller 170 then analyses the position of the one or more stand-off pins 108 and/or grip pins 112 within a subsequent frame of the video signal. The controller 170 compares the actual position of each stand-off pin 108 and/or grip pin 112 to an expected location and updates the position of each detected stand-off pin 108 and/or grip pin 112. If new stand-off pin 108 and/or grip pin 112 is detected in the subsequent frame, then the new stand-off pin 108 and/or grip pin 112 is assigned a new unique identifier.

In one or more embodiments, the controller 170 tracks the outer edge of the substrate 150 within the video signal. The controller 170 compares the position of the outer edge of the substrate 150 to a desired position of the outer edge of the substrate 150 stored within the memory 174 of the controller 170. If the controller 170 determines that the position of the outer edge of the substrate 150 within the video signal is outside of a predetermined tolerance of the desired position of the outer edge of the substrate 150 stored within the memory 174 of the controller 170, the controller determines that the substrate 150 has become displaced within the processing chamber 100. If the controller 170 determines that substrate 150 has become displaced within the processing chamber 100 then the controller 170 generates an error message. If the controller 170 generates an error message then the controller 170 stops the method 400.

In one or more embodiments while performing operation 410, the controller 170 performs sub-method 504. Sub-method 504 includes determining the presence of a dripping nozzle mechanism. The dripping nozzle mechanism can include the first nozzle mechanism 120 and/or the second nozzle mechanism 140. In one or more embodiments, after first nozzle mechanism 120 and/or the second nozzle mechanism 140 apply a fluid to the substrate 150, the first nozzle mechanism 120 and/or the second nozzle mechanism 140 may continue to drip the fluid, which can negatively affect substrate processing. The controller 170 determines whether or not fluid is dripping from the first nozzle mechanism 120, the second nozzle mechanism 140, or a combination thereof by analyzing one or more visual attributes of the first nozzle mechanism 120 and/or the second nozzle mechanism 140 within the video signal.

When fluid drips from the first nozzle mechanism 120 and/or the second nozzle mechanism 140 one or more visual attributes are captured within the video signal. The controller 170 identifies these one or more visual attributes, such as motion, shape, reflectivity, or a combination thereof. The controller 170 then compares these one or more visual attributes to one or more predefined patterns stored within the memory 174 of the controller 170. The one or more predefined patterns correspond to the expected values of the one or more visual attributes when water dripping is present. If the controller 170 determines that the one or more visual attributes match the one or more predefined patterns, then the controller 170 determines that water is dripping from the first nozzle mechanism 120 and/or the second nozzle mechanism 140. If the controller 170 determines that water is dripping from the first nozzle mechanism 120 and/or the second nozzle mechanism 140 then the controller 170 generates an error message. If the controller 170 generates an error message then the controller 170 stops the method 400.

In one or more embodiments, while performing operation 410, the controller 170 performs sub-method 506. Sub-method 506 includes determining the presence of a fluid on an outer surface of the rotor cover. In one or more embodiments, during operation 407, the substrate 150 may splash fluid on the outer surface of the rotor cover 106, which can negatively affect substrate processing. The controller 170 determines whether or not fluid is splashing on the outer surface of the rotor cover 106 by analyzing one or more visual attributes of the rotor cover 106 within the video signal.

When fluid is splashing on the rotor cover 106, one or more visual attributes are captured within the video signal. The controller 170 identifies these one or more visual attributes, such as motion, shape, reflectivity, or a combination thereof. The controller 170 then compares these one or more visual attributes to one or more predefined patterns stored within the memory 174 of the controller 170. The one or more predefined patterns correspond to the expected values of the one or more visual attributes when fluid splashing is present. In one or more embodiments, an ultraviolet (UV) light is emitted onto the rotor cover 106 during the method 400. The controller 170 determines whether or not fluid splashing is present by comparing the reflectivity of the fluid droplets to the reflectivity of rotor cover 106. If an area of the rotor cover 106 reflects a greater amount of UV light than the rest of the rotor cover 106, then the controller 170 determines that fluid splashing is present. If the controller 170 determines that the one or more visual attributes match the one or more predefined patterns, then the controller 170 determines fluid is splashing on the rotor cover 106. If the controller determines fluid is splashing on the rotor cover 106 then the controller 170 generates an error message. If the controller 170 generates an error message then the controller 170 stops the method 400.

In one or more embodiments, the controller 170 while performing operation 410, the controller 170 performs sub-method 508. Sub-method 508 includes determining the presence of a fluid on the substrate. While performing operation 407, fluid is removed from the substrate 150 by rotating the substrate at a high velocity. In one or more embodiments, after operation 407 is performed, fluid is still present on the substrate, which can negatively affect device performance. The controller 170 determines whether or not fluid is present on the substrate 150 by analyzing one or more visual attributes of the substrate 150 within the video signal.

When fluid is present on the substrate 150, one or more visual attributes are captured within the video signal. The controller 170 identifies these one or more visual attributes, such as motion, shape, reflectivity, or a combination thereof. The controller 170 then compares these one or more visual attributes to one or more predefined patterns stored within the memory 174 of the controller 170. The one or more predefined patterns correspond to the expected values of the one or more visual attributes when fluid is present. If the controller 170 determines that the one or more visual attributes match the one or more predefined patterns, then the controller 170 determines fluid is present on the substrate 150. If the controller determines fluid is present on the substrate 150 then the controller 170 generates an error message. If the controller 170 generates an error message then the controller 170 stops the method 400.

It is contemplated that operation 410 may be performed prior to operations 406 and/or 407, simultaneously to operation 406 and/or 407, or after operation 406 and/or 407. In one or more embodiments, operation 410 is repeated continuously while performing the method 400.

In one or more embodiments, after operation 410 is performed, an error message is generated by the controller 170 and the method 400 is stopped. In one or more embodiments, the error message is transmitted to a user, who can address the error within the processing chamber 100 before continuing the method 400. In one or more embodiments, if an error message is generated by the controller 170, the controller 170 analyses the error message and automatically addresses the error before continuing the method 400.

Benefits of the present disclosure include improved error detection during a substrate processing operation, such as a cleaning operation. The improved error detection allows the user to identify and correct errors to avoid substrates from getting damaged during processing. Improved error detection further leads to improved device performance, decreased processing times, increased device yield, improved component life time, decreased maintenance, and decreased costs.

It is contemplated that one or more aspects disclosed herein may be combined. As an example, one or more aspects, features, components, operations and/or properties of the processing chamber 100, the substrate 150, the first drive motor 122, the second drive motor 128, the process rotor 102, the collection rotor 104, stand-off pins 108, the grip pins 112, the rotor cover 106, the enclosure 118, the first nozzle mechanism 120, second nozzle mechanism 140, the one or more sensors 194, the controller 170, the method 400, and/or method 500 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing chamber, comprising:
an enclosure defining an internal volume;
a process rotor disposed within the internal volume having a plurality of grip pins configured to releasably hold a substrate, the process rotor being configured to rotate and to move between a lowered position and a raised position;
one or more sweep arms having a nozzle mechanism configured to apply a fluid to the substrate;
a rotor cover surrounding the process rotor, wherein an annular volume is defined between the rotor cover and the process rotor;
one or more optical sensors configured to detect of one or more components within the internal volume of the processing chamber, the one or more optical sensors configured to transmit a video signal; and
a controller in communication with the one or more optical sensors, wherein the controller is configured to receive the video signal and identify one or more errors based on the video signal.

2. The processing chamber of claim 1, wherein the one or more optical sensors are disposed within the internal volume.

3. The processing chamber of claim 1, wherein the one or more errors comprise at least one of:
a displaced substrate;
a dripping nozzle mechanism;
a fluid present on a rotor cover; or
a fluid present on a substrate.

4. The processing chamber of claim 1, wherein the controller is further configured to:
track a plurality of pins disposed within the internal volume to determine a detected number of pins;
compare the detected number of pins to a desired number of pins;
determine whether the detected number of pins varies from the desired number of pins; and
generate an error message if the detected number of pins varies from the desired number of pins.

5. The processing chamber of claim 1, wherein the controller is further configured to:
track a position of an outer edge of a substrate disposed within the internal volume;
compare the position the outer edge of the substrate to a desired position;
determine whether the position the outer edge of the substrate varies from the desired position by more than a predetermined tolerance; and
generate an error message if the position the outer edge of the substrate varies from the desired position by more than a predetermined tolerance.

6. The processing chamber of claim 1, wherein the controller is further configured to:
track one or more visual attributes of a nozzle mechanism disposed within the internal volume;
compare the one or more visual attributes to one or more predefined patterns;
determine whether the one or more visual attributes vary from the one or more predefined patterns by more than a predetermined tolerance; and
generate an error message if the one or more visual attributes vary from the one or more predefined patterns by more than a predetermined tolerance.

7. The processing chamber of claim 1, wherein the controller is further configured to:
track one or more visual attributes of a rotor cover disposed within the internal volume;
compare the one or more visual attributes on a first area of the rotor cover to one or more visual attributes on a second area of the rotor cover;
determine whether the one or more visual attributes on the first area vary from the one or more visual attributes on the second area; and
generate an error message if the one or more visual attributes vary one another.

8. The processing chamber of claim 1, wherein the controller is further configured to:
track one or more visual attributes of a substrate disposed within the internal volume;
compare the one or more visual attributes to one or more predefined patterns;
determine whether the one or more visual attributes vary from the one or more predefined patterns by more than a predetermined tolerance; and
generate an error message if the one or more visual attributes vary from the one or more predefined patterns by more than a predetermined tolerance.

9. A method of monitoring a process chamber, comprising:
capturing one or more images of one or more components within an internal volume of a processing chamber;
generating a video signal;
determining, with a controller, a presence of one or more errors of the one or more components based on the video signal, the one or more errors comprising at least one of:
a displaced substrate;
a dripping nozzle mechanism;
a fluid on a rotor cover; or
a fluid on a substrate.

10. The method of claim 9, wherein determining a presence of a displaced substrate comprises:
tracking a plurality of pins disposed within the internal volume to determine a detected number of pins;
comparing the detected number of pins to a desired number of pins;
determining whether the detected number of pins varies from the desired number of pins; and
generating an error message if the detected number of pins varies from the desired number of pins.

11. The method of claim 9, wherein determining a presence of a displaced substrate comprises:
tracking a position of an outer edge of a substrate disposed within the internal volume;
comparing the position the outer edge of the substrate to a desired position;
determining whether the position the outer edge of the substrate varies from the desired position by more than a predetermined tolerance; and
generating an error message if the position the outer edge of the substrate varies from the desired position by more than a predetermined tolerance.

12. The method of claim 9, wherein determining a presence of a dripping nozzle mechanism comprises:
tracking one or more visual attributes of a nozzle mechanism disposed within the internal volume;
comparing the one or more visual attributes to one or more predefined patterns;
determining whether the one or more visual attributes vary from the one or more predefined patterns by more than a predetermined tolerance; and
generating an error message if the one or more visual attributes vary from the one or more predefined patterns by more than a predetermined tolerance.

13. The method of claim 9, wherein determining a presence of a fluid on a rotor cover comprises:
tracking one or more visual attributes of a rotor cover disposed within the internal volume;
comparing the one or more visual attributes on a first area of the rotor cover to one or more visual attributes on a second area of the rotor cover;
determining whether the one or more visual attributes on the first area vary from the one or more visual attributes on the second area; and
generating an error message if the one or more visual attributes vary from one another.

14. The method of claim 9, wherein determining a presence of a fluid on a substrate comprises:
tracking one or more visual attributes of a substrate disposed within the internal volume;
comparing the one or more visual attributes to one or more predefined patterns;
determining whether the one or more visual attributes vary from the one or more predefined patterns by more than a predetermined tolerance; and
generating an error message if the one or more visual attributes vary from the one or more predefined patterns by more than a predetermined tolerance.

15. A non-transitory computer readable medium, storing instructions that when executed by one or more processors of a system, cause the system to:
determine a presence of one or more errors of one or more components disposed within an internal volume of a processing chamber based on a video signal, the one or more errors comprising at least one of:
a displaced substrate;
a dripping nozzle mechanism;
a fluid present on a rotor cover; or
a fluid present on a substrate.

16. The computer readable medium of claim 15, wherein determining a presence of a displaced substrate comprises:
tracking a plurality of pins disposed within the internal volume to determine a detected number of pins;
comparing the detected number of pins to a desired number of pins;
determining whether the detected number of pins varies from the desired number of pins; and
generating an error message if the detected number of pins varies from the desired number of pins.

17. The computer readable medium of claim 15, wherein determining a presence of a displaced substrate comprises:
tracking a position of an outer edge of a substrate disposed within the internal volume;
comparing the position the outer edge of the substrate to a desired position;
determining whether the position the outer edge of the substrate varies from the desired position by more than a predetermined tolerance; and
generating an error message if the position the outer edge of the substrate varies from the desired position by more than a predetermined tolerance.

18. The computer readable medium of claim 15, wherein determining a presence of a dripping nozzle mechanism comprises:
tracking one or more visual attributes of a nozzle mechanism disposed within the internal volume;
comparing the one or more visual attributes to one or more predefined patterns;
determining whether the one or more visual attributes vary from the one or more predefined patterns by more than a predetermined tolerance; and
generating an error message if the one or more visual attributes vary from the one or more predefined patterns by more than a predetermined tolerance.

19. The computer readable medium of claim 15, wherein determining a presence of a fluid on a rotor cover comprises:
tracking one or more visual attributes of a rotor cover disposed within the internal volume;
comparing the one or more visual attributes on a first area of the rotor cover to one or more visual attributes on a second area of the rotor cover;
determining whether the one or more visual attributes vary on the first area vary from the one or more visual attributes on the second area; and
generating an error message if the one or more visual attributes vary from one another.

20. The computer readable medium of claim 15, wherein determining a presence of a fluid on a substrate comprises:
tracking one or more visual attributes of a substrate disposed within the internal volume;
comparing the one or more visual attributes to one or more predefined patterns;
determining whether the one or more visual attributes vary from the one or more predefined patterns by more than a predetermined tolerance; and
generating an error message if the one or more visual attributes vary from the one or more predefined patterns by more than a predetermined tolerance.
